(19) United States
(12) Patent Application Publication
(10) Pub. No.: US 2010/0315774 A1
(43) Pub. Date: Dec. 16, 2010

(54) Wireless Card Adapters

(76) Inventors: Paul N. Walker, Cypress, TX (US); Kenneth D. Reddix, Spring, TX (US); Adam G. Sanderson, Cypress, TX (US)

Correspondence Address: HEWLETT-PACKARD COMPANY;Intellectual Property Administration, 3404 E. Harmony Road, Mail Stop 35, FORT COLLINS, CO, 80528, US

(21) Appl. No.: 12/867,304

(22) PCT Filed: Mar. 7, 2008
(86) PCT No.: PCT/US08/56180

§ 371 Date: Aug. 12, 2010

(51) Int. Cl. G06F 1/16; H05K 7/00

(52) U.S. Cl. 361/679.58; 361/748

(57) ABSTRACT

A wireless card adapter including a body portion having a proximal end and a distal end and including mounting holes formed adjacent the proximal end, and brackets extending from the distal end of the body portion configured to receive a half mini card and mounting holes that align with mounting holes of the half mini card when the half mini card has been slid along the brackets until the half mini card contacts the distal end of the body portion, the mounting holes of the brackets being configured to receive fasteners that secure the half mini card to the adapter.

### BACKGROUND

It is now common to provide internal wireless cards in notebook computers that enable wireless networking. An example of an internal wireless card is the so-called “mini” card shown in FIG. 1. As indicated in FIG. 1, the mini card 100 comprises an elongated circuit board 102 having a top surface 104 to which various components are mounted. Provided at one end of the circuit board are electrical contacts 106 configured to couple with contacts of a connector provided on a further circuit board, such as a computer motherboard. Provided at the other end of the circuit board 102 are mounting holes 108 that are adapted to receive standoffs also mounted to the motherboard that are used to support and secure the mini card 100 to the motherboard.

Recently, manufacturers have developed smaller wireless cards commonly referred to as “half mini” cards. An example of a half mini card is shown in FIG. 2. As indicated in that figure, the half mini card 200 is the same width as the full mini card 100 but is only about half as long. Other than its length, the half mini card 200 is similar in construction to the full mini card 100. Therefore, the half mini card 200 comprises a circuit board 202 having a top surface 204 to which components are mounted, electrical contacts 206 provided at a first end, and mounting holes 208 provided at a second end.

Although the smaller size of the half mini card is advantageous in some cases, it is disadvantageous in others. Specifically, computer manufacturers may need the capability to install either a full mini card or a half mini card in a given computer depending upon customer specifications. In such a case the manufacturer may need to design and produce two motherboard versions for the computer, one configured to mount a full mini card and another configured to mount a half mini card. Because producing and stocking multiple versions of a motherboard increases the costs of the manufacturer, it would be preferable to be able to alternatively accommodate the full mini card or the half mini card with a single motherboard.

### BRIEF DESCRIPTION OF THE DRAWINGS

The disclosed wireless card adapters can be better understood with reference to the following drawings. The components in the drawings are not necessarily to scale.

FIG. 1 is a perspective view of a known full mini card.

FIG. 2 is a perspective view of a known half mini card.

FIG. 3 is a perspective view of an embodiment of a half mini card adapter.

FIG. 4 is a perspective view of the half mini card adapter of FIG. 3 shown connected to a half mini card.

FIG. 5 is a perspective view of an embodiment of a motherboard configured to receive a full mini card.

FIG. 6 is a perspective view of a half mini card mounted the motherboard of FIG. 5 using the half mini card adapter.

FIG. 7 is a perspective view of a computing device and a perspective view of a motherboard used within the computing device.

### DETAILED DESCRIPTION

As described above, it is undesirable to manufacture multiple versions of a computer motherboard to enable the motherboard to alternatively receive both full mini cards and half mini cards. As described in the following, however, a single motherboard can be used with both types of cards when a mini card adapter is used. In some embodiments, the half mini card adapter attaches to the half mini card and provides additional length to the half mini card so that it has the same general form factor as a full mini card. In such a case, the motherboard can be specifically configured to receive full mini cards, but can also receive half mini cards when used in conjunction with the half mini card adapter.

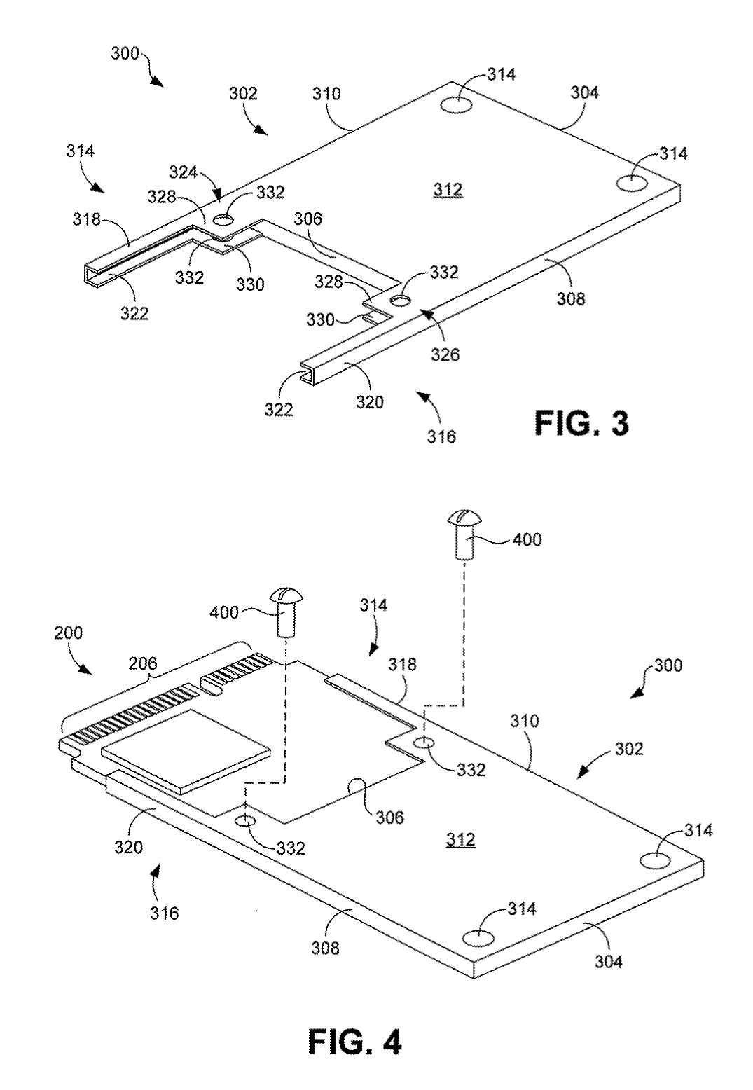

Referring now in more detail to the drawings in which like numerals indicate corresponding parts throughout the views, FIG. 3 illustrates an embodiment of a half mini card adapter 300. Generally speaking, the adapter 300 is configured for use with a wireless card commonly referred to as the half mini card. Such cards are approximately 30 millimeters (mm) wide, approximately 26.8 mm long, and approximately 1 mm thick (excluding surface-mounted components). As described above, half mini cards may have the general configuration illustrated in FIG. 2. Such cards may configured for wireless communications via IEEE 802.11 and may comprise electrical contacts configured in accordance with the peripheral component interconnect (PCI) or PCI Express (PCIe) standard. Therefore, the half mini card 200 may alternatively be referred to as a wireless card, PCI Express half mini card, PCIe half mini card, or other appropriate designation.

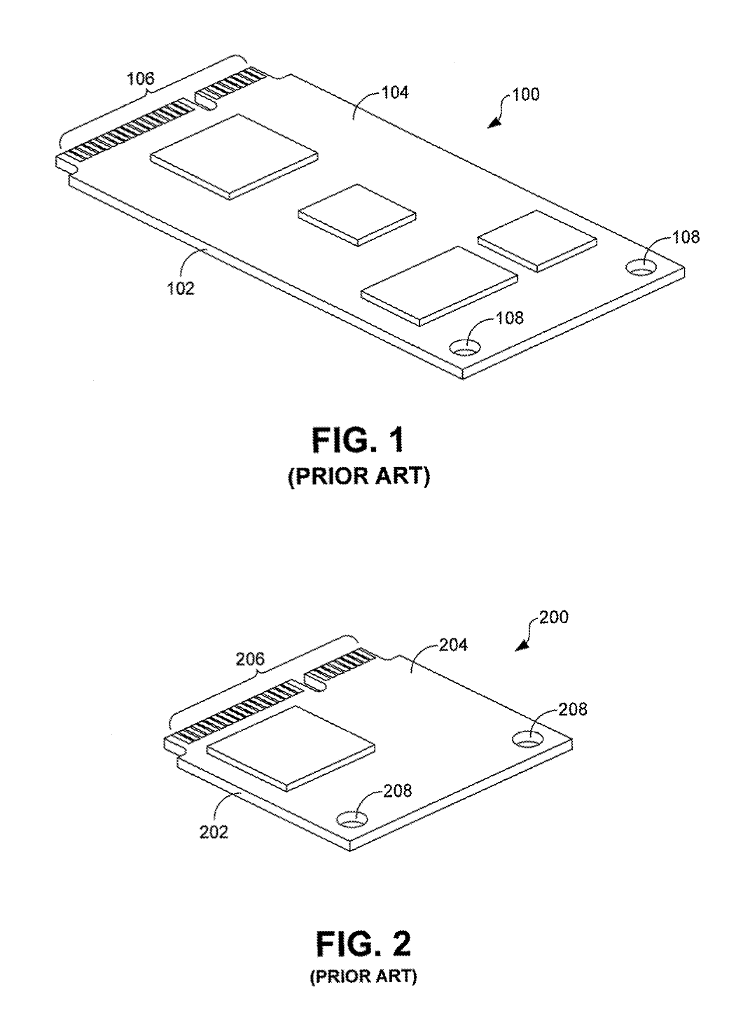

With further reference to FIG. 1, the adapter 300 comprises a generally rectangular body portion 302 having a first or proximal side or end 304, a second or distal side or end 306, and opposed lateral sides 308 and 310. In addition, the body portion 302 comprises a top surface 312 and a bottom surface (not visible). In some embodiments, the body portion 302 is a solid member constructed of a suitable material, such as plastic. In other embodiments, the body portion 302 is a hollow member constructed of one or two components made of a suitable material, such as sheet metal or plastic. For example, the body portion 302 can comprise a single piece of sheet metal or upper and lower plastic halves that are snap fit or bonded together. Regardless, the body portion 302 comprises two mounting holes 314 that are provided adjacent the proximal end 304. The mounting holes 314 are sized and spaced the same as the mounting holes of a full mini card. Therefore, the holes 314 are approximately 5.2 mm in diameter and are spaced approximately 24.2 millimeters apart (center to center). In some embodiments, the centers of the holes 314 are spaced approximately 21.25 mm from the distal end 306 of the body portion 302. As described below, that dimension results in the adapter 300 and the half mini card it receives having the same general form factor as a full mini card.

Extending outward from the distal end 306 of the body portion 302 are two opposed brackets 314 and 316 that are configured to receive a half mini card. In some embodiments, the brackets 314, 316 are constructed of the same material as the body portion 302. Alternatively, the brackets 314, 316 and the body portion 302 can be constructed of dissimilar materials. For example, the body portion 302 can be composed of plastic while the brackets 314, 316 can be composed of sheet metal, if desired.

Each bracket 314, 316 comprises an elongated arm 318, 320 that defines an elongated slot 322 in which a lateral edge of the half mini card can be received. When those edges are so received within the slots 318, the half mini card can be slid along the slots until the half mini card comes into contact with the distal end 306 of the body portion 302. In some embodiments, the arms 318, 320 have generally C-shaped (or U-shaped) cross-sections.

Adjacent the distal end 306 of the body portion 302, each bracket 314, 316 comprises a card securing portion 324 and 326. Each card securing portion 324, 326 comprises a top portion or member 328 and a bottom portion or member 330 between which the half mini card can be positioned. Formed through at least the top members 328, and optionally through the bottom members 330, are mounting holes 332 that are adapted to receive fasteners, such as screws or bolts, that secure the adapter 300 to the half mini card and vice versa. In some embodiments, the top members 328 and/or the bottom members 330 are provided with bosses configured to receive threads of the fasteners. In other embodiments, the edges of the mounting holes 332 receive those threads. In still other embodiments, the fasteners may be used in conjunction with threaded nuts.

FIG. 4 illustrates the adapter 300 in use with a half mini card 200 first shown in FIG. 2. As indicated in FIG. 4, the half mini card 200 has been slid along the slots 322 of the brackets 314, 316 to place the end of the card in contact with the distal end 306 of the adapter body portion 302 (see FIG. 3). When the half mini card 200 is placed in that position, the mounting holes 208 of the half mini card align with the mounting holes 332 provided in the card securing portions 324, 326 of the adapter 300. Accordingly, the half mini card can be fixedly secured to the adapter 300 using fasteners 400. As is further illustrated in FIG. 4, the arms 318, 320 of the brackets 314, 316 may not extend along the entire length of the half mini card 200, but may extend along a major portion of that length.

As is apparent from comparison of FIG. 4 and FIG. 1, the half mini card 200 and the adapter 300 when attached together have the same, general form factor of the full mini card 100. More importantly, the relative positions of the mounting holes 314 of the adapter 300 and the electrical contacts 206 of the half mini card 200 are substantially the same as those of the contacts 106 and the mounting holes 108 of the full mini card 100. Specifically, the end of the half mini card that comprises the contacts 206 is spaced approximately 48.05 mm from the centers of the mounting holes 314 of the adapter 300. That spacing is made possible by controlling the distance between the mounting holes 314 and the distal end 306 of the adapter 300 to be approximately 21.25 mm. Because of that, the half mini card 200 and the adapter 300 can be used in combination to mount to a circuit board, such as a motherboard, that is specifically configured to receive and support a full mini card.

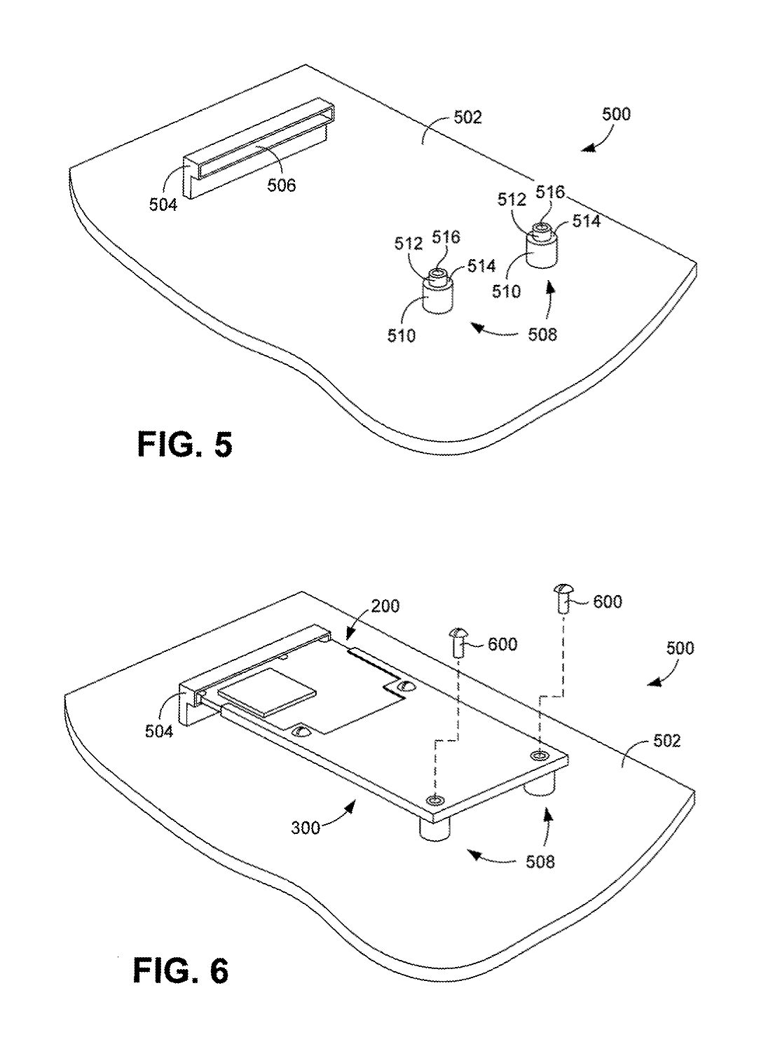

FIG. 5 provides an example of a circuit board 500 that is specifically configured to receive and support a full mini card. As indicated in FIG. 500, the circuit board 500 includes a top surface 502 to which a connector 504 that is configured to connect a full mini card is mounted. The connector 504 comprises a receptacle 506 into which the full mini card can be received. Also mounted to the surface 502 are standoffs 508 that are configured to support the full mini card and receive fasteners that secure the full mini card to the standoffs. The standoffs 508 each comprise a base portion 510 and a top portion 512 that is configured to pass through a mounting hole of the full mini card. Between the base and top portions 510 and 512 is a support surface 514 upon which the full mini card can rest. Formed within the top portion 512 is a threaded opening 516 adapted to receive a fastener. Notably, the standoffs 508 are spaced from the connector 506 a distance at which the mounting holes of the full mini card align with the top portions 512 of the standoffs when the full mini card is inserted into the receptacle 506.

FIG. 6 illustrates the half mini card 200 and its attached adapter 300 being installed on the circuit board 500 in the position specifically configured for a full mini card. As is apparent from FIG. 6, the adapter 300 provides additional length to the half mini card 200 that enables the half mini card to be supported by the standoffs 508. In particular, the top portions 512 of the standoffs 508 are received by the mounting holes 314 of the adapter 300 and fasteners 600 are threaded into the threaded openings 516 to securely hold the half mini card 200 in place once it has been inserted into the receptacle 506 of the connector 504.

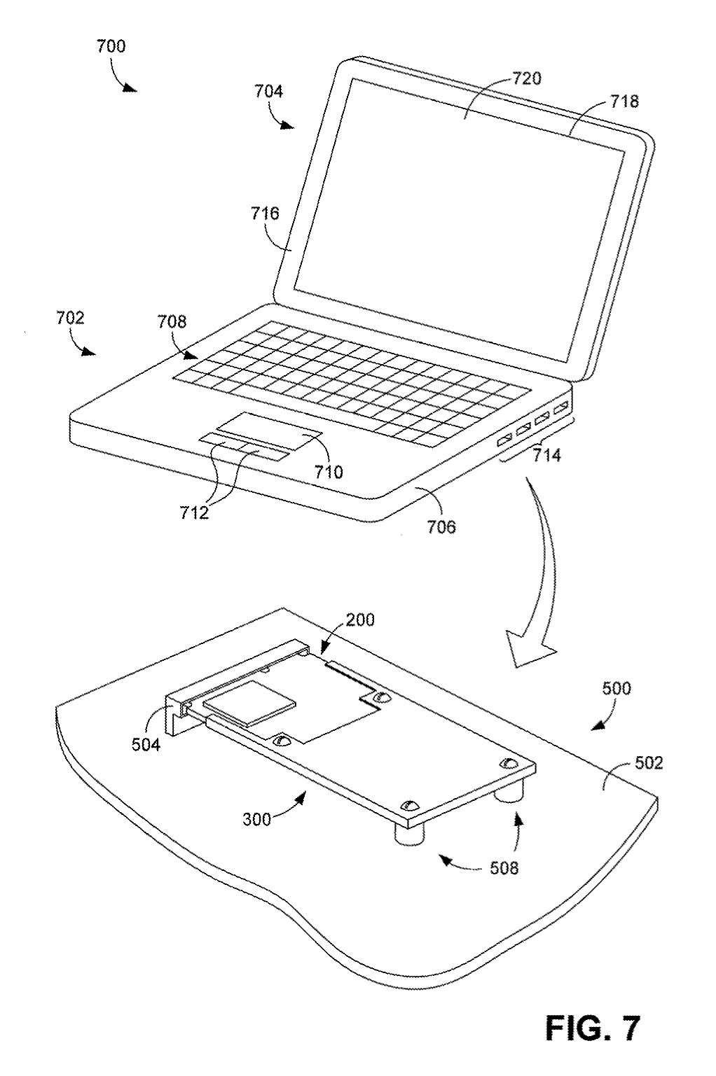

FIG. 7 illustrates an example computing device 100 that incorporates the circuit board 500, and the half mini card 200 and adapter 300 that are mounted thereto. As indicated in FIG. 7, the computing device 700 includes a base portion 702 and a display portion 704 that are attached to each other with a hinge mechanism (not shown). The base portion 702 includes an outer housing 706 that surrounds various internal components of the computing device 700, such as a processor, memory, hard drive, and the like. Also included in the base portion 702 are user input devices, including a keyboard 708, a mouse pad 710, and selection buttons 712, as well as various ports 714 that are accessible through the housing 706. The display portion 702 includes its own outer housing 716. Formed within the housing 716 is an opening 718 through which a display device 720 may be viewed.

1. A wireless card adapter comprising:
a body portion having a proximal end and a distal end and including mounting holes formed adjacent the proximal end; and
brackets extending from the distal end of the body portion configured to receive a half mini card and mounting holes that align with mounting holes of the half mini card when the half mini card has been slid along the brackets until the half mini card contacts the distal end of the body portion, the mounting holes of the brackets being configured to receive fasteners that secure the half mini card to the adapter.

2. The adapter of claim 1, wherein the half mini card and the adapter have a form factor of a full mini card when they are secured together.

3. The adapter of claim 1, wherein a distance between electrical contacts of the half mini card and the mounting holes of the body portion when the half mini card and the adapter are secured together is approximately the same as a distance between electrical contacts and mounting holes of a full mini card.

4. The adapter of claim 1, wherein the mounting holes of the body portion are configured to receive standoffs of a circuit board to which the half mini card is to be mounted.

5. The adapter of claim 1, wherein the brackets comprise elongated arms that define slots configured to receive edges of the half mini card.

6. The adapter of claim 1, wherein centers of the mounting holes of the body portion are spaced approximately 21.25 millimeters from the distal end of the body portion.

7. A wireless card adapter comprising:
a body portion having a proximal end and a distal end and including mounting holes formed adjacent the proximal end, the mounting holes being spaced approximately 24.2 millimeters apart from each other center to center and spaced approximately 21.25 millimeters from the distal end; and
two opposed brackets extending from the distal end of the body portion, the brackets including elongated arms that define slots configured to receive edges of a half mini card and card securing portions configured to secure the half mini card between the brackets when the half mini card has been slid along the slots of the elongated arms until the half mini card contacts the distal end of the body portion, the card securing portions of the brackets including mounting holes configured to receive threaded fasteners that secure the half mini card to the adapter.

8. Apparatus for wireless networking comprising:
a half mini wireless card having first and second ends and lateral edges, the half mini wireless card further including electrical contacts provided adjacent the first end and mounting holes provided adjacent the second end;
an adapter connected to the half mini card, the adapter including:
a body portion having a proximal end and a distal end and further including mounting holes formed adjacent the proximal end, and
brackets extending from the distal end of the body portion in which the edges of the half mini card are provided, the brackets having mounting holes that are aligned with the mounting holes of the half mini card; and
fasteners provided through the mounting holes of both the adapter and the half mini card.

9. The apparatus of claim 8, wherein the half mini wireless card has a length of approximately 26.8 millimeters.

10. The apparatus of claim 8, wherein the half mini wireless card and the adapter have a form factor of a full mini wireless card.

11. The apparatus of claim 8, wherein a distance between the first end of the half mini wireless card and centers of the mounting holes of the body portion of the adapter is approximately 48.5 millimeters.

12. The apparatus of claim 8, wherein the mounting holes of the body portion of the adapter are configured to receive standoffs of a circuit board to which the half mini wireless card is to be mounted.

13. The apparatus of claim 8, wherein the brackets comprise elongated arms that define slots in which the edges of the half mini wireless card are provided.

14. The apparatus of claim 8, wherein centers of the mounting holes of the body portion of the adapter are spaced approximately 21.25 millimeters from the distal end of the body portion.

15. A computing device comprising:
a motherboard having a top surface to which is mounted a wireless card connector and standoffs configured to support and secure a wireless card; and
apparatus for wireless networking including a half mini wireless card having first and second ends and lateral edges, the half mini wireless card further including electrical contacts provided adjacent the first end and mounting holes provided adjacent the second end, and an adapter connected to the half mini card, the adapter including a body portion having a proximal end and a distal end and further including mounting holes formed adjacent the proximal end and brackets extending from the distal end of the body portion in which the edges of the half mini card are provided, the brackets having mounting holes that are aligned with the mounting holes of the half mini card, wherein the half mini wireless card and the adapter are secured together with fasteners provided through the mounting holes of the adapter and the half mini wireless card;
wherein the first end of the half mini wireless card is positioned within the wireless card connector of the motherboard and the standoffs of the motherboard are provided through the mounting holes of the body portion of the adapter and wherein the adapter is secured to the standoffs with fasteners that extend through the mounting holes of the body portion of the adapter and into the standoffs.

16. The computing device of claim 15, wherein the half mini wireless card has a length of approximately 26.8 millimeters.

17. The computing device of claim 15, wherein a distance between the first end of the half mini wireless card and centers of the mounting holes of the body portion of the adapter is approximately 48.5 millimeters.

18. The computing device of claim 15, wherein the brackets comprise elongated arms that define slots in which the edges of the half mini wireless card are provided.

19. The computing device of claim 15, wherein centers of the mounting holes of the body portion of the adapter are spaced approximately 21.25 millimeters from the distal end of the body portion.

20. The computing device of claim 15, wherein the computing device is a notebook computer.
